(19) United States
(12) Patent Application Publication
(10) Pub. No.: US 2013/0335661 A1
(43) Pub. Date: Dec. 19, 2013

(54) LIQUID CRYSTAL DISPLAY DEVICES AND METHODS OF MANUFACTURING LIQUID CRYSTAL DISPLAY DEVICES

(71) Applicants: Jung-Bae BAE, Yongin-City (KR); Yong-Koo HER, Yongin-City (KR)

(72) Inventors: Jung-Bae BAE, Yongin-City (KR); Yong-Koo HER, Yongin-City (KR)

(21) Appl. No.: 13/772,387

(22) Filed: Feb. 21, 2013

(30) Foreign Application Priority Data
Jun. 13, 2012 (KR) 10-2012-0062938

(51) Int. Cl. G02F 1/1335; G02F 1/1368; H01L 33/58

(52) U.S. Cl. CPC G02F 1/133512; H01L 33/58; G02F 1/1368
USPC 349/42; 438/29; 349/106

(57) ABSTRACT

A liquid crystal display device including a first region, a second region and a third region, the display device include a first substrate, a circuit structure on the first substrate in the first region, a first electrode electrically connected to the circuit structure, a second substrate opposing the first substrate, a black matrix on the second substrate in the first region and the second region, a color filter on the second substrate in the third region, a second electrode on the color filter and the black matrix, and a liquid crystal structure between the first substrate and the second substrate. A first thickness of a first portion of the black matrix in the first region is less than a second thickness of a second portion of the black matrix in the second region.

### CROSS-REFERENCE TO RELATED APPLICATION

This application claims priority under 35 USC §119 to Korean Patent Application No. 10-2012-0062938 filed on Jun. 13, 2012 in the Korean Intellectual Property Office (KIPO), the contents of which are herein incorporated by reference in its entirety.

### BACKGROUND

A liquid crystal display (LCD) device may display images by controlling a transmittance of light according to an orientation of liquid crystal molecules in a liquid crystal layer by varying an electric field generated between two electrodes. Since the liquid crystal display may not emit light itself, an additional light source is used in the LCD device. The LCD device has been used widely because of relatively low power consumption and mobility thereof.

### SUMMARY

Embodiments may be realized by providing a liquid crystal display device including a first region, a second region and a third region. The liquid crystal display device may include a first substrate, a circuit structure disposed on the first substrate in the first region, a first electrode electrically connected to the circuit structure, a second substrate opposed to the first substrate, a black matrix disposed on the second substrate in the first region and the second region, a color filter disposed on the second substrate in the third region, a second electrode disposed on the color filter and the black matrix and a liquid crystal structure disposed between the first substrate and the second substrate. A first thickness of a first portion of the black matrix in the first region is smaller than a second thickness of a second portion of the black matrix in the second region.

The circuit structure may include a memory device, a switching device, a level shifter circuit, a gate driver, a source driver and/or a timing controller. The black matrix may include an organic material. The liquid crystal display device may further include an insulation layer disposed on the first substrate in the first region to cover the circuit structure.

The first electrode may extend on the insulation layer, and may pass through the insulation layer to contact the circuit structure. A distance between the second electrode and the circuit structure may increase because of a thickness difference between the first portion and the second portion of the black matrix. The second electrode may sufficiently cover the color filter.

Embodiments may also be realized by providing a liquid crystal display device that includes a first region, a second region and a third region. The liquid crystal display device includes a first substrate, a circuit structure disposed on the first substrate in the first region, a first electrode disposed on the first substrate in the second region and the third region electrically contacting the circuit structure, a second substrate opposed to the first substrate, a black matrix disposed on the second substrate in the first region and the second region, a color filter disposed on the second substrate in the third region, a second electrode disposed on the color filter and the black matrix and a liquid crystal structure disposed between the first substrate and the second substrate. The black matrix has a stepped portion in the first region.

The second electrode may be substantially uniformly disposed along a profile of the stepped portion of the black matrix. A distance between the second electrode and the circuit structure may increase because of the stepped portion of the black matrix. The second electrode may include a transparent conductive material, and the circuit structure may include a memory device, a switching device, a level shifter circuit, a gate driver, a source driver and/or a timing controller.

The liquid crystal display device may further include an insulation layer disposed on the first substrate in the first region to cover the circuit structure. The first electrode may extend on the insulation layer, and may pass through the insulation layer to contact the circuit structure.

Embodiments may also be realized by providing a method of manufacturing a liquid crystal display device that includes a first region, a second region, and a third region. In the method, a circuit structure is formed on a first substrate in the first region. A first electrode is formed on the first substrate in the second region and the third region, the first electrode electrically contacting the circuit structure. A black matrix including a stepped portion is formed on the second substrate in the first region and the second region. A color filter is formed on the second substrate in the third region. A second electrode is formed on the black matrix and the color filter. The first substrate is combined with the second substrate. A liquid crystal structure is formed between the first substrate and the second substrate.

An insulation layer may be formed on the first substrate in the first region to cover the circuit structure. A hole may be formed through the insulation layer to partially expose the circuit structure, and the first electrode may contact the circuit structure through the hole. Forming the black matrix may include forming a preliminary black matrix on the second substrate in the first region, the second region and the third region and etching the preliminary black matrix using a photoresist pattern having a stepped portion.

Etching the preliminary black matrix may include forming a photoresist film on the preliminary black matrix, forming a mask including a light shielding region, a translucent region and a transparent region on the photoresist film, and patterning the photoresist film using the mask to form the photoresist pattern having the stepped portion on the preliminary black matrix. The translucent region of the mask may correspond to the first region, the light shielding region of the mask may correspond to the second region, and the transparent region of the mask may correspond to the third region.

Etching the preliminary black matrix may include sufficiently removing the preliminary black matrix in the third region and partially removing the preliminary black matrix in the first region to form the black matrix having the stepped portion in the first region. A distance between the second electrode and the circuit structure may increase because of a thickness difference between the first portion and the second portion of the black matrix.

### BRIEF DESCRIPTION OF THE DRAWINGS

Example embodiments will be more clearly understood from the following detailed description taken in conjunction with the accompanying drawings. FIGS. 1 to 10 represent non-limiting, example embodiments as described herein.

FIG. 1 is a cross-sectional view illustrating a liquid crystal display device in accordance with example embodiments;

FIGS. 2 to 7 are cross-sectional views depicting stages in a method of manufacturing a liquid crystal display device in accordance with example embodiments;

FIG. 8 is a circuit diagram illustrating a circuit structure of a liquid crystal display device in accordance with example embodiments;

FIG. 9 is a graph illustrating a simulation result for an electrical operation of the circuit structure of a liquid crystal display device; and

FIG. 10 is a graph illustrating a simulation result for an electrical operation of the circuit structure of a liquid crystal display device in accordance with example embodiments.

### DETAILED DESCRIPTION

Various embodiments will be described more fully hereinafter with reference to the accompanying drawings, in which some embodiments are shown. Embodiments, however, be embodied in many different forms and should not be construed as limited to the exemplary embodiments set forth herein. Rather, these exemplary embodiments are provided so that this description will be thorough and complete, and will fully convey the scope to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

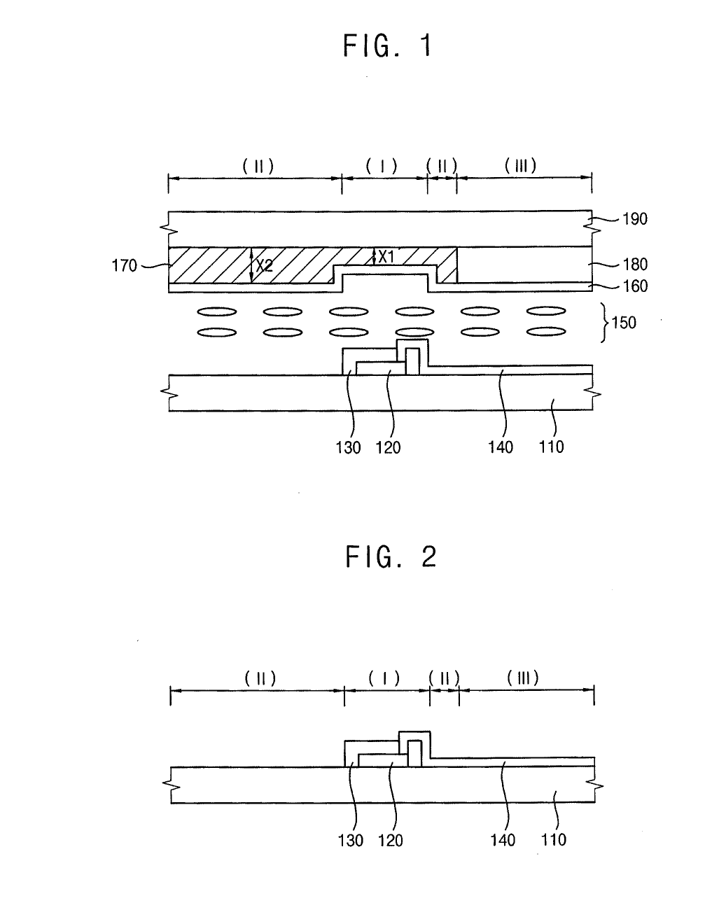

FIG. 1 is a cross-sectional view illustrating a liquid crystal display device in accordance with example embodiments.

Referring to FIG. 1, the liquid crystal display device in accordance with example embodiments may include a first substrate 110, a circuit structure 120, an insulation layer 130, a first electrode 140, a second electrode 160, a black matrix 170, a color filter 180, a second substrate 190, and a liquid crystal structure 150. The liquid crystal structure 150 may be disposed between the first substrate 110 and the second substrate 190.

The liquid crystal display device may include a first region I, a second region II, and a third region III according to the arrangement of the black matrix 170. In this case, the first substrate 110 and/or the second substrate 190 may be divided into the first region I, the second region II and the third region III by the position of the black matrix 170. In example embodiments, the second region II may substantially surround and/or enclose the first region I. The third region III may be located adjacent to the second region II, e.g., adjacent to one side of the second region II. For example, at least a portion of the second region II may be disposed to be interposed between the first region I and the third region III.

Each of the first substrate 110 and the second substrate 190 may include a transparent insulating material such as glass, quartz, a transparent resin, a transparent ceramic, etc. The first and the second substrates 110 and 190 may be arranged substantially parallel to each other, or may be arranged substantially perpendicular to each other.

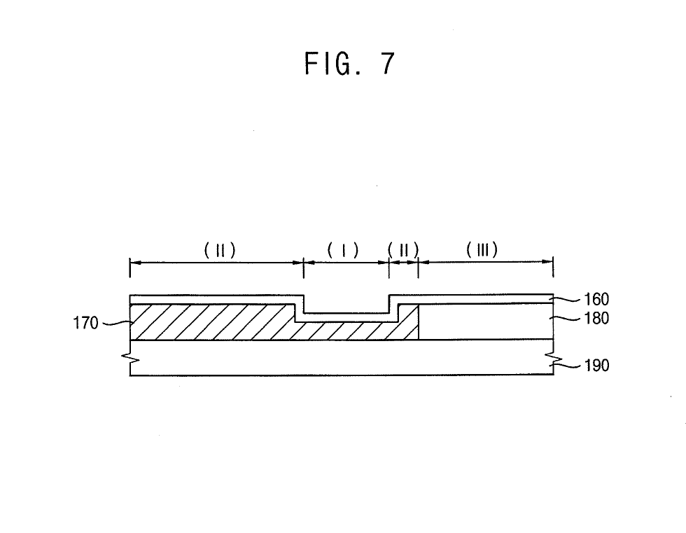

Referring to FIG. 1, the circuit structure 120, the insulation layer 130, and the first electrode 140 may be disposed on the first substrate 110. The circuit structure 120 may be provided in the first region I of the first substrate 110, e.g., only in the first region I. The configuration of the circuit structure 120 will be described with reference to FIG. 7. In example embodiments, a stepped portion of the black matrix 170 may be positioned in the first region I where the circuit structure 120 may be disposed, e.g., so as to correspond with the placement of the circuit structure 120. The stepped portion of the black matrix 170 may prevent or considerably reduce a decrease in an aperture ratio of the liquid crystal display device due to the circuit structure 120.

For example, the circuit structure 120 may include various circuits including memory devices such as ones of a static random access memory (SRAM), a dynamic random access memory (DRAM) or a magneto-resistive random access memory (MRAM), switching devices such as an amorphous silicon gate thin film transistor (ASG-TFT) or oxide semiconductor transistor, a level shifter circuit, a gate driver, a source driver, a timing controller, etc.

The insulation layer 130 may cover the circuit structure 120 in the first region I of the first substrate 110. The insulation layer 130 may be only in the first region I or a small portion of the insulation layer may extend into an adjacent side of the second region II. The insulation layer 130 may include a hole (not illustrated) which may partially expose the circuit structure 120. For example, the insulation layer 130 may include a transparent insulating material such as a transparent plastic, a transparent resin, etc. The insulation layer 130 may electrically isolate the circuit structure 120 from other components disposed on the first substrate 110.

Referring now to FIG. 1, the first electrode 140 may be disposed on the first substrate 110 and the insulation layer 130. In example embodiments, the first electrode 140 may extend from the third region III of the first substrate 110 onto the insulation layer 130 in the first region I. For example, the first electrode 140 may have a first portion in the first region I, which first portion is in contact with the circuit substrate 120 and the insulation layer 130. The first electrode 140 may also include a second portion extending across the second region II and a third portion in the third region III. The first, second, and third portions may be integrally formed as only continuous layer. The first electrode 140 may serve as a pixel electrode to which a data signal may be applied from a wiring such as a data line.

In example embodiments, the first electrode 140 may be disposed on the insulation layer 130 to substantially fill a hole in the insulation layer 130 that exposes the circuit substrate 120, so that the first electrode 140 may be electrically connected to the circuit structure 120. In some example embodiments, a contact, a pad, or a plug substantially filling the hole in the insulation layer 130 may be additionally provided. In this case, the first electrode 140 may be electrically connected to the circuit structure 120 through the contact, the pad, or the plug.

The first electrode 140 may include a transparent conductive material. For example, the first electrode 140 may include at least one of indium tin oxide (InSnxOy; ITO), indium zinc oxide (InZnxOy; IZO), indium oxide (InOx), zinc oxide (ZnOx), gallium oxide (GaOx), tin oxide (SnOx), titanium oxide (TiOx), etc. These may be used alone or in a combination thereof. The first electrode 140 may have a single layer structure or a multi layer structure.

The color filter 180 may be disposed on the second substrate 190 substantially opposed to the first substrate 110. The color filter 180 may be positioned in the third region III of the second substrate 190 whereas the color filter 180 may not be disposed in the first region I and the second region II of the second substrate 190. In example embodiments, the color filter 180 may include at least one of a red color filter for a red (R) color of light, a green color filter for a green (G) color of light, a blue color filter for a blue (B) color of light, etc. Pixels including the red color filter, the green color filter, or the blue color filter may be arranged in a predetermined sequence for displaying images.

The black matrix 170 may be disposed on the second substrate 190 adjacent to the color filter 180. The black matrix 170 may be disposed in the first region I and the second region II of the second substrate 190. The black matrix 170 may shield a leakage of light between adjacent color filters 180 to improve a contrast ratio of the liquid crystal display device.

In example embodiments, portions of the black matrix 170 may have substantially different thicknesses in the first region I and the second region II. The first region I and the second region II may be defined by the thickness of the black matrix 170. That is, a first thickness X1 of a first portion of the black matrix 170 in the first region I may be substantially smaller than a second thickness X2 of a second portion of the black matrix 170 in the second region II. For example, the thicknesses of the first and the second portions of the black matrix 170 may change abruptly between the first region I and the second region II. Therefore, the black matrix 170 may include a stepped portion in the first region I, e.g., the first region I may be defined by an indented region of the black matrix 170.

The thickness of the first portion of the black matrix 170 may be adjusted to prevent or considerably reduce a coupling phenomenon between the circuit structure 120 and the second electrode 160 (e.g., a common electrode) according to a type of the circuit structure 120. For example, the thickness of the first portion of the black matrix 170 may vary depending on dimensions and components of the circuit structure 120. The black matrix 170 having the stepped portion may be obtained using a mask including a light shielding region and a translucent region such as a half tone mask or a half tone slit mask. In some example embodiments, the black matrix 170 including the stepped portion may be formed by a partial etching process.

The black matrix 170 may include an organic material having a relatively high light shielding characteristic and a relatively low reflectivity. The organic material used in the black matrix 170 may include an initiator, monomers, a binder, a solvent, a pigment, an additive, etc. The initiator may initiate a polymerization process, and the pigment may determine the light shielding characteristic of the black matrix 170. The additive may be selectively added to improve an adhesive characteristic and a coating characteristic of the organic material.

The second electrode 160 may be disposed on the color filter 180 and the black matrix 170. The second electrode 160 may serve as the common electrode, and may extend form the third region III to the first region I and the second region II. For example, the second electrode 160 may substantially entirely cover the black matrix 170 and the color filter 180. The second electrode 160 may be substantially uniformly disposed in the first region I and the second region II along a profile of the stepped portion of the black matrix 170. In example embodiments, the second electrode 160 may include a stepped portion in the first region I in accordance with the stepped portion of the black matrix 170 in the first region I. That is, the second electrode 160 may have the stepped portion above the circuit structure 120.

The second electrode 160 also may include a transparent conductive material. For example, the second electrode 160 may include indium tin oxide (ITO), indium zinc oxide (IZO), indium oxide, zinc oxide, gallium oxide, tin oxide, titanium oxide, etc. The second electrode 160 may have a single layer structure or a multi layer structure.

In example embodiments, the second electrode 160 may have a structure depending on the stepped portion of the black matrix 170. That is, a distance between the second electrode 160 and the second substrate 190 in the first region I may be substantially smaller than a distance between the second electrode 160 and the second substrate 190 in the second region II. When a distance between the first substrate 110 and the second substrate 190 is constant in the first region I, second region II and the third region III, a distance between the first substrate 110 and the second electrode 160 in the first region I may be substantially larger than a distance between the first substrate 110 and the second electrode 160 in the second region II. That is, the distance between the circuit structure 120 and the second electrode 160 may increase due to the stepped portion of the black matrix 170, so that the coupling phenomenon between the circuit structure 120 and the second electrode 160 may be prevented or reduced to prevent an abnormal signal transmission.

In example embodiments, the second electrode 160 may substantially cover the color filter 180. Therefore, an out-gassing of organic layer(s) included in the color filter 180 may be prevented or greatly reduced, and a deterioration of the color filter 180 may be prevented, thereby improving an afterimage characteristics.

Referring now to FIG. 1, the liquid crystal structure 150 may be disposed in the first region I, the second region II, and the third region III between the first substrate 110 and the second substrate 190. The liquid crystal structure 150 may include liquid crystal molecules having optical and electrical characteristics such as an anisotropic refractivity and an anisotropic dielectricity, which may be arranged in a predetermined way. In the liquid crystal structure 150, the arrangement of the liquid crystal molecules may be changed by an electrical field generated between the first electrode 140 and the second electrode 160, so that a light transmittance may be controlled by the arrangement of the liquid crystal molecules. In example embodiments, an additional element such as a spacer (not illustrated) or a partition (not illustrated) may be disposed between the first electrode 140 and the second electrode 160 to restrict the movement of the liquid crystal molecules and to ensure a distance between the first electrode 140 and the second electrode 160.

FIGS. 2 to 7 are cross-sectional views illustrating a method of manufacturing a liquid crystal display device in accordance with example embodiments.

Referring to FIG. 2, a circuit structure 120 may be formed on a first substrate 110 in the first region I. In example embodiments, the circuit structure 120 may include various circuits including memory devices such as ones of a static random access memory (SRAM), a dynamic random access memory (DRAM) or a magneto-resistive random access memory (MRAM), switching devices such as an amorphous silicon gate thin film transistor (ASG-TFT) or oxide semiconductor transistor, a level shifter circuit, a gate driver, a source driver, a timing controller, etc.

An insulation layer 130 may be formed in the first region I of the first substrate 110 to cover the circuit structure 120. The insulation layer 130 may be formed using an inorganic material such as silicon oxide, silicon oxynitride, silicon nitride, silicon oxycarbide, silicon carbon nitride, etc. In some example embodiments, the insulation layer 130 may be formed using a transparent organic material such as benzocyclobutene (BCB), acryl resin, etc.

A first electrode 140 may be formed on the first substrate 110 and the insulation layer 130. The first electrode 140 may partially cover the insulation layer 130 in the second region II, and may extend to the third region III on the first substrate 110. For example, the first electrode 140 may be formed by one of a sputtering process, a printing process, a spray process, a chemical vapor deposition process, an evaporation process, a pulsed laser deposition process, etc. In example embodiments, the first electrode 140 may be obtained by forming a first conductive layer (not illustrated) on the first substrate 100 and the insulation layer 130 and by patterning the first conductive layer by a photolithography process or an etching process using an additional etching mask.

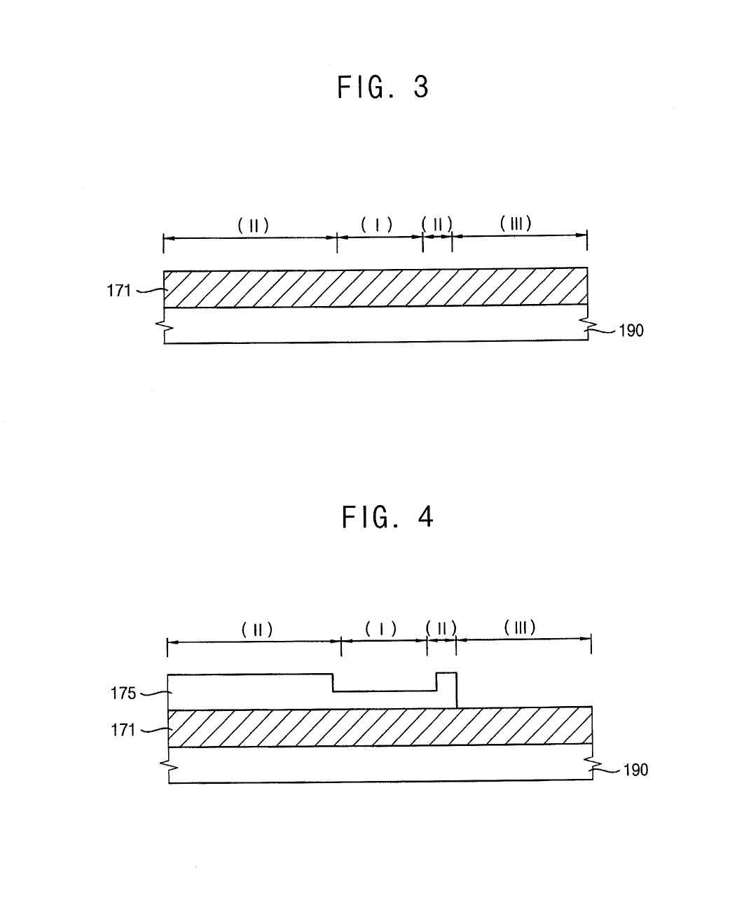

Referring to FIG. 3, a preliminary black matrix 171 may be formed on the second substrate 190, which second substrate 190 may be processed separately from the first substrate 110. The preliminary black matrix 171 may have a predetermined thickness depending on a predetermined optical density value. The preliminary black matrix 171 may be formed in the first region I, the second region II, and the third region III of the second substrate 190. For example, the preliminary black matrix 171 may be formed by a spin coating process, a slit coating process, or a spin and slit coating process. After the coating process, the preliminary black matrix 171 may be heated above a predetermined temperature to polymerize the monomers in the preliminary black matrix 171 (i.e., a soft baking process).

Referring to FIG. 4, a photoresist film (not illustrated) may be formed on the preliminary black matrix 171. The photoresist film may include a first portion in the first region I, a second portion in the second region II, and a third portion in the third region III.

In example embodiments, a mask (not illustrated) including a light shielding region and a translucent region such as a half tone mask or a half tone slit mask may be formed or arranged on the photoresist film. Further, the mask may include a transparent region adjacent to the light shielding region. In this case, the second portion of the photoresist film may be positioned under the light shielding region of the mask, and the third portion of the photoresist film may be disposed under the transparent region of the mask. Further, the first portion of the photoresist film may be positioned under the semi transparent region of the mask, which may have a light transmittance substantially larger than that of the light shielding region and substantially smaller than that of the transparent region.

In example embodiments, an exposure process irradiating a light onto the photoresist film may be performed using the mask, and then a developing process may be performed to partially remove the exposed photoresist layer. For example, the third portion of the photoresist film, which may be fully exposed by the light during the exposure process, may be sufficiently removed by the developing process. However, the first portion of the photoresist film, which may be partially exposed by the light, may be partially removed by the developing process. Therefore, a photoresist pattern 175 having a stepped portion in the first region I may be formed from the photoresist film. The stepped portion of the photoresist pattern 175 may substantially correspond to the circuit structure 120 disposed in the first region I of the first substrate 110.

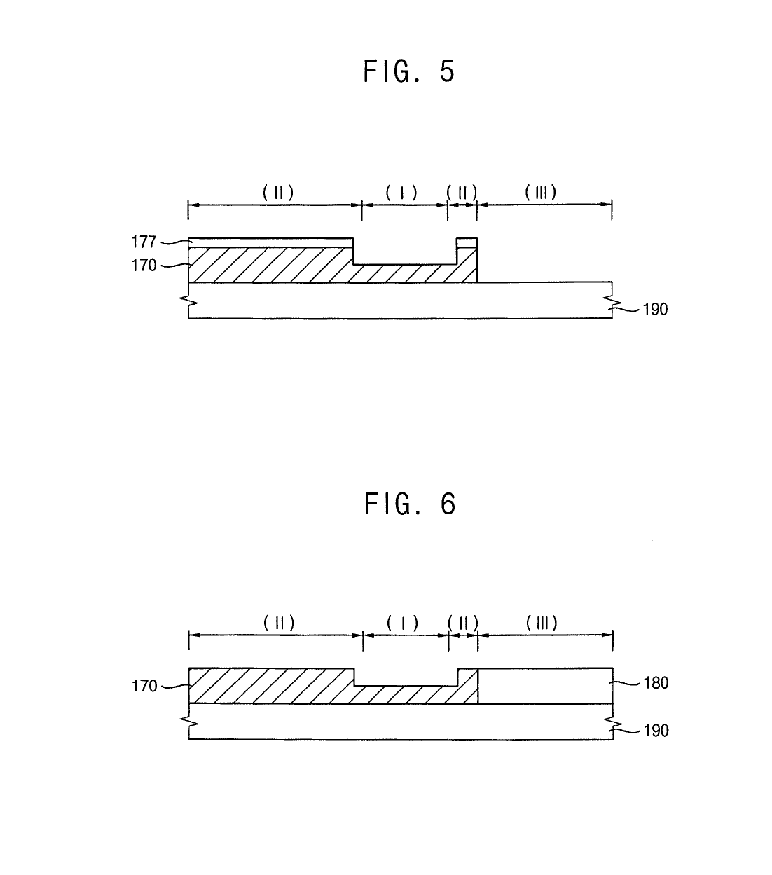

Referring to FIG. 5, the preliminary black matrix 171 may be partially removed by an etching process using the photoresist pattern 175 as an etching mask, so that a black matrix 170 may be formed in the first region I and the second region II of the second substrate 190. In this case, a portion of the preliminary black matrix 171 in the third region III, which may not be covered by the photoresist pattern 175, may be sufficiently removed. However, a portion of the preliminary black matrix 171 in the first region I, which may be covered by the photoresist pattern 175 having a relatively small thickness, may be partially removed whereas a portion of the preliminary black matrix 171 in the second region II may not be removed. Therefore, the black matrix 170 may be formed to include a first portion having a first thickness X1 and a second portion having a second thickness X2 which is substantially larger the first thickness X1. That is, the black matrix 170 may include a stepped portion in the first region I caused by the stepped portion of the photoresist pattern 175. In this case, the stepped portion of the black matrix 170 on the second substrate 190 may substantially correspond to the circuit structure 120 on the first substrate 110.

Then, a remaining photoresist pattern 177 may be removed from the black matrix 170. For example, the remaining photoresist pattern 177 may be removed by a stripping process, an ashing process, a cleaning process, etc.

As described above, the black matrix 170 may be formed using the etching mask including the light shielding region, the translucent region, and the transparent region, so that the black matrix 170 including the stepped portion may be formed by a single etching process. Therefore, misalignment may be prevented or reduced, and a manufacturing cost of the liquid crystal display device may be reduced.

Referring to FIG. 6, a color filter 180 may be formed on the second substrate 190 in the third region III where the black matrix 170 may not be formed. Therefore, the color filter 180 may contact a sidewall of the black matrix 170. The color filter 180 may have a thickness substantially the same as or substantially similar to that of the second thickness X2 of the second portion of the black matrix 170. In example embodiments, the color filter 180 may include a red color filter, a green color filter and a blue color filter depending on the pixels of the liquid crystal display device. The red color filter may be formed by coating a photosensitive resin including a dye absorbing/radiating a red color of light on the second substrate 190, and then patterning the photosensitive resin using a photolithography process. The green color filter and the blue color filter may be formed by substantially similar processes.

As illustrated in FIG. 6, the color filter 180 in the third region III may not be substantially overlapped by the black matrix 170 in the first region I and the second region II. Accordingly, the color filter 180 and the black matrix 170 in the second region II may be adjacent to each other and may be substantially coplanar so that the color filter 180 does not overhang the black matrix 170. In other example embodiments, the color filter 180 may be partially overlapped with the black matrix 170. For example, the color filter 180 may partially extend on the black matrix 170 in the second region II.

As described above, the color filter 180 may be formed by a photolithography process. However, example embodiments of forming the color filter 180 may not be limited to the above-described process. For example, the color filter 180 may be formed by a printing process, a laser induced thermal image process, etc.

Referring to FIG. 7, a second electrode 160 may be formed on the black matrix 170 and the color filter 180. The second electrode 160 may be formed using a transparent conductive material by a sputtering process, a printing process, a spray process, a chemical vapor deposition process, an evaporation process, a pulsed laser deposition process, etc. The second electrode 160 may extend from the third region III to the first region I and the second region II.

In example embodiments, a second conductive layer (not illustrated) may be formed on the black matrix 170 and the color filter 180, and then the second conductive layer may be patterned by a photolithography process or an etching process using an additional etching mask, thereby forming the second electrode 160. The black matrix 170 may have the stepped portion in the first region I, so that the second electrode 160 may also have a stepped portion in the first region I. For example, the second electrode 160 may include the stepped portion having a shape of a recess.

A spacer (not illustrated), a cell gap maintaining member (not illustrated) or a sealing member (not illustrated) may be provided between the first substrate 110 and the second substrate 190, and then the first substrate 110 and the second substrate 190 may be combined with each other while maintaining a distance between the first substrate 110 and the second substrate 190.

A liquid crystal structure 150 may be formed between the first substrate 110 and the second substrate 190 as illustrated in FIG. 1. The liquid crystal structure 150 may be formed on the first substrate 110 and/or the second substrate 190 by a printing process, a spray process, etc. Alternatively, the liquid crystal structure 150 may be injected between the first substrate 110 and the second substrate 190.

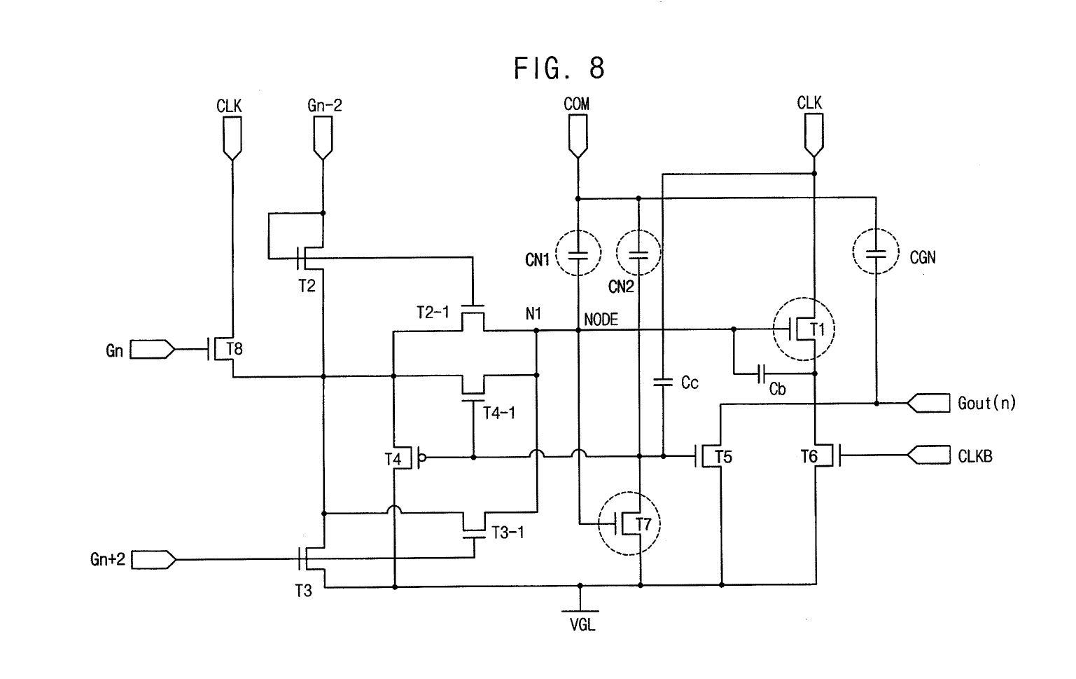

FIG. 8 is a circuit diagram illustrating a circuit structure of a liquid crystal display device in accordance with example embodiments.

Referring to FIG. 8, the circuit structure 120 may include an amorphous silicon thin film transistor (a-Si TFT) gate drive shift register circuit. The shift register circuit may include a pull-up drive transistor, a pull-down drive transistor, a gate output driver, etc. The shift register circuit may include a first capacitor CN1 disposed between a source voltage terminal COM and a first node N1, a second capacitor CN2 disposed between the source voltage terminal COM and a second node N2, and a third capacitor Cgn disposed between the source voltage terminal COM and the output terminal Gout(n). Additionally, the shift register circuit may include a first clock signal terminal CLK and a second clock signal terminal CLKB for supplying clock signals. The shift register circuit may also include other capacitors such as a capacitor Cc connected to the first clock signal terminal CLK and a capacitor Cb connected to the second clock signal terminal CLKB.

The shift register circuit may include a plurality of transistors such as T1, T2, T2-1, T3, T3-1, T4, T4-1, T5, and T6. The plurality of transistors may be connected to ones of the other elements in the shift register circuit such as those discussed above, terminals Gn, Gn+2, Gn−2, voltage gate line VGL, etc.

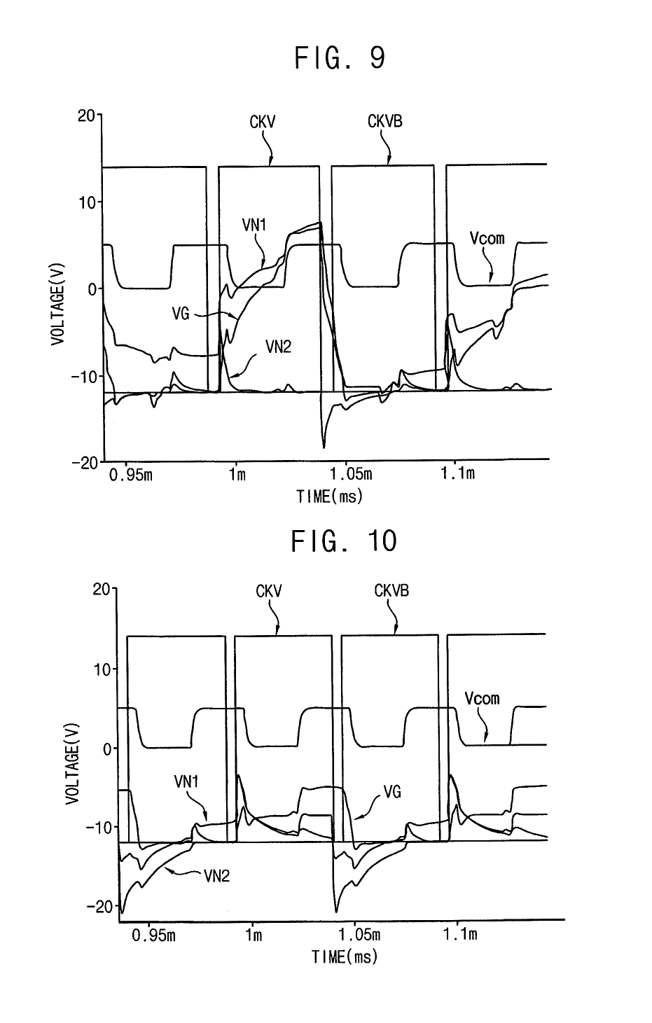

FIG. 9 is a graph illustrating a simulation result for an electrical operation of the circuit structure of a liquid crystal display device. The graph in FIG. 9 may illustrate the electrical operation of the circuit structure, e.g., an ASG circuit.

Referring to FIG. 9, “CKV” and “CKVB” may represent a voltage change at the first and the second clock signal terminals CLK and CLKB, respectively. “Vcom” may indicate a voltage change at the source voltage terminal COM. “VN1” may denote a voltage change at the first node N1, “VN2” may represent a voltage change at the second node N2, and “VG” may indicate a voltage change at the output terminal Gout(n). The graph in the FIG. 9 may illustrate a simulation result, when the circuit structure and the common electrode (e.g., the second electrode) are spaced apart by a distance of about 5 μm. In the liquid crystal display device referenced in FIG. 9, a coupling phenomenon between the first node N1 and the common electrode may result in a ripple phenomenon, which may cause an abnormal change in a voltage VN1 at the first node N1; thereby degrading signal transmission characteristics.

FIG. 10 is a graph illustrating a simulation result for an electrical operation of the circuit structure of a liquid crystal display device in accordance with example embodiments.

The graph in FIG. 10 may illustrate the electrical operation of the circuit structure, e.g., an ASG circuit. Referring to FIG. 10, “CKV” and “CKVB” may represent a voltage change at the first and the second clock signal terminals CLK and CLKB, respectively. “Vcom” may denote a voltage change at the source voltage terminal COM. “VN1” may indicate a voltage change at the first node N1, “VN2” may denote a voltage change at the second node N2, and “VG” may represent a voltage change at the output terminal Gout(n). The graph in the FIG. 10 may illustrate a simulation result, when the circuit structure and the second electrode (e.g., the common electrode) are spaced apart by a distance of about 6 μm in accordance with example embodiments.

As illustrated in FIG. 10, a distance between the circuit structure and the second electrode may increase, so that a coupling capacitance between the circuit structure and the second electrode may decrease by about 20% compared with that of the liquid crystal display device referenced in FIG. 9. As a result, a ripple phenomenon causing an abnormal voltage change VN1 at the first node N1 may sufficiently decrease such that a signal transmission failure from the circuit structure may decrease.

By way of summation and review, liquid crystal display devices may include color filters for implementing colors of the light, and a black matrix for shielding a leakage light between the adjacent color filters and improving a contrast ratio of the light crystal display devices. However, a liquid crystal display device may have a relatively small distance between a circuit structure for controlling an operation of each pixel and a common electrode of the pixels, so that a coupling phenomenon between the circuit structure and the common electrode may degrade the quality of the images of the liquid crystal display device.

In contrast, exemplary embodiments relate to liquid crystal display devices and methods of manufacturing liquid crystal display devices in which the quality of the images is improved. More particularly, example embodiments relate to liquid crystal display devices including black matrixes having stepped portions and methods of manufacturing liquid crystal display devices including black matrixes having stepped portions.

According to example embodiments, a liquid crystal display device may have a sufficient distance between the second electrode (e.g., a common electrode) and the circuit structure caused by a black matrix having a stepped portion, so that a coupling phenomenon between the second electrode and the circuit structure may be reduced or prevented. As a result, enhanced signal transmission characteristics from the circuit structure may improve the quality of the images of the liquid crystal display device according.

Accordingly, in the liquid crystal display device of exemplary embodiments, the coupling phenomenon between the circuit structure and the common electrode may be effectively reduced or prevented to enhance signal transmission characteristics from the circuit structure; thereby improving quality of images displayed thereof. The liquid crystal display device according to exemplary embodiments may be employed in general display apparatuses and various electronic apparatuses such as e-books, customer products, etc.

The foregoing is illustrative of embodiments and is not to be construed as limiting thereof. Although a few embodiments have been described, those skilled in the art will readily appreciate that many modifications are possible in the embodiments without materially departing from the teachings. Accordingly, all such modifications are intended to be included within the scope of the invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A liquid crystal display device including a first region, a second region, and a third region, the display device comprising:
a first substrate;
a circuit structure on the first substrate in the first region;
a first electrode electrically connected to the circuit structure;
a second substrate opposing the first substrate;
a black matrix on the second substrate in the first region and the second region, a first thickness of a first portion of the black matrix in the first region being less than a second thickness of a second portion of the black matrix in the second region;
a color filter on the second substrate in the third region;
a second electrode on the color filter and the black matrix; and
a liquid crystal structure between the first substrate and the second substrate.

2. The liquid crystal display device of claim 1, wherein the circuit structure includes at least one selected from a memory device, a switching device, a level shifter circuit, a gate driver, a source driver, and a timing controller.

3. The liquid crystal display device of claim 1, wherein the black matrix includes an organic material.

4. The liquid crystal display device of claim 1, further comprising an insulation layer on the first substrate in the first region, the insulation layer covering the circuit structure.

5. The liquid crystal display device of claim 4, wherein the first electrode extends on the insulation layer and passes through the insulation layer to contact the circuit structure.

6. The liquid crystal display device of claim 1, wherein a distance between the second electrode and the circuit structure is increased based on a difference between the first thickness of the first portion and the second thickness of the second portion of the black matrix.

7. The liquid crystal display device of claim 1, wherein the second electrode substantially covers the color filter.

8. A liquid crystal display device including a first region, a second region, and a third region, comprising:
a first substrate;
a circuit structure on the first substrate in the first region;
a first electrode on the first substrate in the second region and the third region, the first electrode electrically contacting the circuit structure;
a second substrate opposing the first substrate;
a black matrix on the second substrate in the first region and the second region, the black matrix having a stepped portion in the first region;
a color filter on the second substrate in the third region;
a second electrode on the color filter and the black matrix; and
a liquid crystal structure between the first substrate and the second substrate.

9. The liquid crystal display device of claim 8, wherein the second electrode is uniformly disposed along a profile of the stepped portion of the black matrix.

10. The liquid crystal display device of claim 9, wherein a distance between the second electrode and the first substrate in the first region having the circuit structure therein is greater than another distance between the second electrode and the first substrate in the second region, based on the stepped portion of the black matrix.

11. The liquid crystal display device of claim 10, wherein:
the second electrode includes a transparent conductive material, and
the circuit structure includes at least one selected from a memory device, a switching device, a level shifter circuit, a gate driver, a source driver, and a timing controller.

12. The liquid crystal display device of claim 8, further comprising an insulation layer on the first substrate in the first region, the insulation layer covering the circuit structure, the first electrode extending on the insulation layer and passing through the insulation layer to contact the circuit structure.

13. A method of manufacturing a liquid crystal display device including a first region, a second region, and a third region, the method comprising:
forming a circuit structure on a first substrate in the first region;
forming a first electrode on the first substrate in the second region and the third region, the first electrode electrically contacting the circuit structure;
forming a black matrix on a second substrate in the first region and the second region, the black matrix including a stepped portion;
forming a color filter on the second substrate in the third region;
forming a second electrode on the black matrix and the color filter;
combining the first substrate with the second substrate; and
forming a liquid crystal structure between the first substrate and the second substrate.

14. The method of claim 13, further comprising forming an insulation layer on the first substrate in the first region to cover the circuit structure.

15. The method of claim 14, further comprising forming a hole through the insulation layer to partially expose the circuit structure, the first electrode contacting the circuit structure through the hole.

16. The method of claim 13, wherein forming the black matrix includes:
forming a preliminary black matrix on the second substrate in the first region, the second region, and the third region, and
etching the preliminary black matrix using a photoresist pattern having a stepped portion.

17. The method of claim 16, wherein etching the preliminary black matrix includes:
forming a photoresist film on the preliminary black matrix,
forming a mask on the photoresist film, the mask including a light shielding region, a translucent region, and a transparent region, and
patterning the photoresist film using the mask to form the photoresist pattern having the stepped portion on the preliminary black matrix.

18. The method of claim 17, wherein the translucent region of the mask corresponds to the first region, the light shielding region of the mask corresponds to the second region, and the transparent region of the mask corresponds to the third region.

19. The method of claim 17, wherein etching the preliminary black matrix includes substantially removing the preliminary black matrix in the third region and partially removing the preliminary black matrix in the first region to form the black matrix having the stepped portion in the first region.

20. The method of claim 19, wherein the black matrix is formed such that a distance between the second electrode and the first substrate in the first region having the circuit structure therein is greater than another distance between the second electrode and the first substrate in the second region, based on a thickness difference between a first portion and a second portion of the black matrix.
